(19) United States
(12) Patent Application Publication
(10) Pub. No.: US 2025/0248280 A1
(43) Pub. Date: Jul. 31, 2025

(54) LAMINATE, LAMINATED FILM, IMAGE DISPLAY DEVICE, AND FOLDABLE DEVICE

(71) Applicant: DAICEL CORPORATION, Osaka (JP)

(72) Inventor: Masashi YOKOYAMA, Tokyo (JP)

(73) Assignee: DAICEL CORPORATION, Osaka (JP)

(21) Appl. No.: 19/034,154

(22) Filed: Jan. 22, 2025

(30) Foreign Application Priority Data
Jan. 26, 2024 (JP) 2024-010560

(51) Int. Cl. H10K 59/80; B32B 27/08; B32B 27/36; H10K 102/00

(52) U.S. Cl. CPC H10K 59/873; B32B 27/08; B32B 27/36; B32B 2255/10; B32B 2255/26; B32B 2307/412; B32B 2307/536; B32B 2307/546; B32B 2307/554; B32B 2307/584; B32B 2457/206; H10K 2102/311

(57) ABSTRACT

Problem

To provide a laminate that can exhibit sufficient bendability without using a compound corresponding to a PFAS.

Solution

The laminate of the present disclosure includes a substrate and a hard coat layer laminated on at least one surface of the substrate. The hard coat layer contains no compound corresponding to a PFAS. The laminate of the present disclosure is further characterized in that a minimum bendable radius is equal to or less than 5 mm in a cylindrical mandrel test in which the laminate is bent with a surface of the hard coat layer of the laminate being convex. In addition, in a bending durability test of the hard coat layer, the number of operations until a crack occurs in the hard coat layer is preferably 10000 or more.

### TECHNICAL FIELD

The present disclosure relates to a laminate, a laminated film, an image display device, and a foldable device.

### BACKGROUND ART

As a cover material used on the outermost surface of an electronic material or display of a television, personal computer, smartphone, or the like, a configuration in which a hard coat layer is laminated to prevent the occurrence of scratches is known. In particular, UV curable resins containing a crosslinkable fluorine compound (PFAS) have been used for such a hard coat layer in order to exhibit wear resistance (for example, see Patent Document 1).

However, the degradability of PFAS type substances is poor, and problems of long-term persistence in the environment and toxicity are known. Thus, from the viewpoint of reducing the environmental impact, there is a demand for a hard coat layer that does not contain a PFAS.

### CITATION LIST

### Patent Literature

Patent Document 1: JP 2016-11365 A

### SUMMARY OF INVENTION

### Technical Problem

However, without PFAS, a hard coat layer has insufficient bendability, and it has been difficult to produce a hard coat layer that exhibits bendability equivalent to that of a product that contains a PFAS.

Therefore, the invention of the present disclosure was created to solve the problems described above, and an object thereof is to provide a laminate that can exhibit sufficient bendability without using a compound corresponding to a PFAS.

### Solution to Problem

The inventors of the present disclosure discovered that a laminate that includes a substrate and a hard coat layer laminated on at least one surface of the substrate and in which the hard coat layer satisfies specific physical property values without containing a compound corresponding to a PFAS can exhibit sufficient bendability without using a fluorine compound. The present disclosure has been completed based on these findings.

The present disclosure provides a laminate including a substrate and a hard coat layer laminated on at least one surface of the substrate, the hard coat layer containing no compound corresponding to a PFAS, wherein the laminate has a minimum bendable radius of 5 mm or less in a cylindrical mandrel test in which the laminate is bent with a surface of the hard coat layer of the laminate being convex.

The laminate is also preferably configured such that in the following bending durability test of the hard coat layer, the number of operations until a crack occurs in the hard coat layer is 10000 or more. In the above configuration, the laminate can exhibit more excellent bending durability.

### Bending Durability Test:

The operations are carried out at a rate of 30 to 60 operations/minute, where in a single operation, the laminate is subjected to 180° bend from a unbended conformation to have a bending radius of 4.0 mm in a direction to make the surface of the hard coat layer convex, and then once again is brought back to the unbended conformation.

In the laminate, preferably no visible scratches are generated on the hard coat layer when the hard coat layer is subjected to a steel wool abrasion test in which #0000 steel wool is rubbed back and forth 1000 times on the surface of the hard coat layer while a load of 750 g/cm² is applied. In the above configuration, the laminate can exhibit more excellent scratch resistance.

In the laminate, the hard coat layer preferably has a haze of 1.0% or less.

The laminate preferably has a haze of 7% or less.

Moreover, preferably, the hard coat layer is a cured product of a curable composition containing one or more curable compounds, and the curable composition contains a polyorganosilsesquioxane as the one or more curable compounds.

Furthermore, the curable composition preferably contains a compound having one or more cationically polymerizable groups and one or more radically polymerizable groups per molecule.

The curable composition preferably further contains a curing catalyst.

The curing catalyst preferably includes a cationic polymerization initiator.

The curing catalyst preferably includes a radical polymerization initiator.

The curable composition preferably further contains a radically curable polyorganosiloxane.

The curable composition preferably contains an aliphatic compound having two or more cationically polymerizable groups per molecule.

The substrate is preferably a transparent substrate.

The laminate preferably has a surface protection film on at least one surface thereof.

The laminate preferably has the hard coat layer on one surface of the substrate and a tacky adhesive layer on the other surface thereof.

The present disclosure also provides an image display device provided with the laminate described above.

The image display device is preferably a foldable display.

The image display device is preferably an organic electroluminescent display device.

The present disclosure also provides a foldable device including the image display device.

### Advantageous Effects of Invention

A laminate according to an embodiment of the present disclosure can exhibit sufficient bendability without using a compound corresponding to a PFAS.

### Description of Embodiments

Note that in the present disclosure, the term “compound corresponding to a PFAS” is a generic term for perfluoroalkyl compounds and polyfluoroalkyl compounds.

### Laminate

A laminate according to an embodiment of the present disclosure includes a substrate and a hard coat layer laminated on at least one surface of the substrate. The hard coat layer contains no compound corresponding to a PFAS. The laminate has a minimum bendable radius of 5 mm or less in a cylindrical mandrel test in which the laminate is bent with the surface of the hard coat layer of the laminate being convex. The laminate according to an embodiment of the present disclosure and having the above configuration can exhibit sufficient bendability without containing a compound corresponding to a PFAS.

The above laminate may have other layers in addition to the substrate and the hard coat layer. Examples of the other layers include a surface protection film, a tacky adhesive layer, an undercoat layer for bonding the substrate and the hard coat layer, an antireflection layer, an anti-glare layer, a fingerprint-resistant layer, an antifouling layer, a scratch and fingerprint-resistant layer, an antibacterial layer, a bonding layer, and a polarizing layer. Here, the other layers may be formed on only one surface (one side) of the substrate, or may be formed on both surfaces (both sides) of the substrate. In addition, when the other layers are formed on both surfaces of the substrate, the same layers may be laminated on each surface, or layers having different thicknesses or compositions may be laminated on the surfaces of the substrate.

The surface protection film protects the surface of the hard coat layer, and the laminate preferably has a surface protection film on at least one surface thereof. When the hard coat layer is formed on both surfaces of the substrate, the surface protection film may be provided on both surfaces of the laminate.

The surface protection film is not particularly limited, and a well-known or commonly used surface protection film can be used. For example, a film having a tacky adhesive agent layer on the surface of a plastic film can be used. Examples of the plastic film include plastic films formed from plastic materials such as polyesters (e.g., polyethylene terephthalate, polyethylene naphthalate), polyolefins (e.g., polyethylene, polypropylene, cyclic polyolefins), polystyrenes, acrylic resins, polycarbonates, epoxy resins, fluororesins, silicone resins, diacetate resins, triacetate resins, polyarylates, polyvinyl chlorides, polysulfones, polyethersulfones, polyether ether imides, polyimides, and polyamides. Examples of the tacky adhesive agent layer include a tacky adhesive agent layer formed from one or more types of well-known and commonly used tacky adhesives such as acrylic tacky adhesives, silicone-based tacky adhesives, natural rubber-based tacky adhesives, synthetic rubber-based tacky adhesives, ethylene-vinyl acetate copolymer-based tacky adhesives, ethylene-(meth)acrylate copolymer-based tacky adhesives, styrene-isoprene block copolymer-based tacky adhesives, and styrene-butadiene block copolymer-based tacky adhesives. The tacky adhesive agent layer may contain various additives (for example, antistatic agents, and slip agents). Note that the plastic film and the tacky adhesive agent layer each may have a single layer configuration or may have a multilayer (multiple layer) configuration. In addition, the thickness of the surface protection film is not particularly limited, and can be appropriately selected.

As the surface protection film, commercially available products can be procured from the marketplace including, for example, “Sunytect” (trade name) series (available from Sun A. Kaken Co., Ltd.), “E-MASK” (trade name) series (available from Nitto Denko Corporation), “Mastack” (trade name) series (available from Fujimori Kogyo Co., Ltd.), “Hitalex” (trade name) series (available from Hitachi Chemical Co., Ltd.), and “Alphan” (trade name) series (available from Oji F-Tex Co., Ltd.).

In the laminate, the tacky adhesive layer is preferably laminated on the surface of the substrate opposite the surface on which the hard coat layer is laminated. That is, when the laminate has the tacky adhesive layer, preferably, the hard coat layer is provided on one surface of the substrate, and the tacky adhesive layer is provided on the other surface of the substrate. In addition, the laminate more preferably has the tacky adhesive layer on one surface.

As the tacky adhesive constituting the tacky adhesive layer, a tacky adhesive similar to the tacky adhesive exemplified with regard to the surface protection film can be used. Among these, from the viewpoint of achieving good transparency and sufficient tacky adhesive strength even when the tacky adhesive layer is thin, an acrylic tacky adhesive and a silicone tacky adhesive are preferable, and an acrylic tacky adhesive is particularly preferable. Note that a single type of the tacky adhesive may be used alone, or two or more types may be used in combination.

The thickness of the tacky adhesive layer is, for example, from 0.1 to 50 μm, preferably from 1 to 45 μm, more preferably from 2 to 40 μm, and even more preferably from 5 to 35 μm.

The tacky adhesive layer can be produced by applying the tacky adhesive to at least one surface of the substrate and curing the tacky adhesive.

In a cylindrical mandrel test performed in accordance with JIS K5600-5-1 in which the laminate is bent with the surface of the hard coat layer being convex, the minimum bendable radius at which cracking does not occur is in a range of 5 mm or less, and preferably 4 mm or less. When the minimum bendable radius is 5 mm or less, sufficient bendability can be exhibited. Note that when the hard coat layer is laminated on both surfaces of the laminate, the above range need only be satisfied on at least one surface.

In a cylindrical mandrel test similarly performed in accordance with JIS K5600-5-1 in which the laminate is bent with the surface of the hard coat layer of the laminate being concave, the minimum bendable radius at which cracking does not occur is preferably in a range of 5 mm or less, more preferably 4 mm or less, and even more preferably 2 mm or less. When the minimum bendable radius is 5 mm or less, sufficient bendability can be exhibited. Note that when the hard coat layer is laminated on both surfaces of the laminate, the above range need only be satisfied on at least one surface.

The pencil hardness of the laminate described above is F or higher and more preferably H or higher, as measured in accordance with JIS K5600-5-4. When the pencil hardness is F or higher, the surface hardness of the laminate becomes sufficient, and wear resistance is easily exhibited. Note that when the hard coat layer is laminated on both surfaces of the laminate, the above range need only be satisfied on at least one surface.

The number of times the operation is carried out until a crack occurs in the hard coat layer is preferably 10000 times or more, and more preferably 30000 times or more, in a bending durability test as follows: the operations are carried out at a rate of 30 to 60 operations/minute, where in a single operation, the laminate is subjected to 180° bend from a unbended conformation to have a bending radius of 4.0 mm in a direction to make the surface of the hard coat layer convex, and then once again is brought back to the unbended conformation. By having the abovementioned configuration, the laminate can exhibit sufficient bending resistance. Note that when the hard coat layer is laminated on both surfaces of the laminate, the above range need only be satisfied on at least one surface.

In addition, the laminate is preferably such that when #0000 steel wool is rubbed back and forth on the surface of the hard coat layer 1000 times at a load of 750 g/cm², no scratches are confirmed on the surface of the hard coat layer. By having the above configuration, the laminate can exhibit wear resistance.

The laminate has a haze value of preferably 7% or less, more preferably 5% or less, even more preferably 3% or less, and particularly preferably 1.5% or less. In addition, the lower limit of the haze is, for example, 0.1%. When the haze is 7% or less, the laminate tends to be suitable for use in applications requiring a high level of transparency. Note that in the present specification, the haze can be measured in accordance with JIS K7136.

The total light transmittance of the laminate is preferably 85% or greater, and more preferably 90% or greater. When the total light transmittance is 85% or greater, the laminate tends to be suitable for use in applications requiring high transparency. In the present specification, the total light transmittance can be measured in accordance with JIS K7361-1.

The thickness of the laminate is preferably from 10 to 1000 μm, more preferably from 30 to 500 μm, and particularly preferably from 50 to 300 μm. When the thickness of the laminate is 10 μm or greater, sufficient surface hardness is easily achieved. In addition, when the thickness is 1000 μm or less, sufficient bendability is easily exhibited.

### Substrate

As the substrate in the laminate according to an embodiment of the present disclosure, a known or commonly used substrate can be used, such as a plastic substrate, a metal substrate, a ceramic substrate, a semiconductor substrate, a glass substrate, a paper substrate, a wood substrate (wooden substrate), and a substrate having a surface that is a coated surface. Among these, the substrate is preferably a transparent substrate, and a plastic substrate is preferable. The substrate may have a single-layer structure or a multi-layer structure, and may be composed of one type of material or two or more types of materials.

The plastic material constituting the plastic substrate is not particularly limited, and examples include various plastic materials including polyesters, such as polyethylene terephthalate (PET) and polyethylene naphthalate (PEN); polyimides; polycarbonates; polyamides; polyacetals; polyphenylene oxides; polyphenylene sulfides; polyethersulfones; polyether ether ketones; cyclic polyolefins such as homopolymers of norbornene-based monomers (addition polymers and ring-opening polymers, etc.), copolymers of norbornene-based monomers and olefin-based monomers (cyclic olefin copolymers such as addition polymers and ring-opening polymers), such as copolymers of norbornene and ethylene, and derivatives thereof; vinyl-based polymers (e.g., acrylic resins such as polymethyl methacrylate (PMMA), polystyrene, polyvinyl chloride, and acrylonitrile-styrene-butadiene resins (ABS resins)); vinylidene-based polymers (e.g., polyvinylidene chloride); cellulose-based resins such as triacetyl cellulose (TAC); epoxy resins; phenol resins; melamine resins; urea resins; maleimide resins; and silicones.

Among these, as the plastic substrate, a substrate excellent in transparency and bending durability is preferably used, and more preferably a polyester film (particularly, PET or PEN), a polyimide film, a cyclic polyolefin film, a polycarbonate film, a TAC film, or a PMMA film is used, and still more preferably a polyester film (particularly, PET or PEN) or a polyimide film is used.

As necessary, the substrate may contain other additives such as an antioxidant, an ultraviolet absorber, a light stabilizer, a heat stabilizer, a crystal nucleating agent, a flame retardant, a flame retardant aid, a filler, a plasticizer, an impact resistance improver, a reinforcing agent, a dispersant, an antistatic agent, a foaming agent, and an antibacterial agent. A single type of additive may be used alone, or two or more types may be used in combination.

A portion or all of the surface of the substrate of the side on which the hard coat layer is laminated may be subjected to a known or commonly-used surface treatment such as a roughening treatment, an easy-adhesion treatment, an antistatic treatment, a sand blasting treatment (sand matting treatment), a corona discharge treatment, a plasma treatment, a chemical etching treatment, a water matting treatment, a flame treatment, an acid treatment, an alkali treatment, an oxidation treatment, an ultraviolet irradiation treatment, or a silane coupling agent treatment. The plastic substrate may be an unstretched film or a stretched film such as a uniaxially stretched film or a biaxially stretched film. A commercially available product can also be used as the substrate.

The thickness of the substrate is, for example, preferably from 1 to 1000 μm, more preferably from 5 to 500 μm, still more preferably from 10 to 400 μm, and particularly preferably from 10 to 300 μm.

### Hard Coat Layer

In the laminate, the hard coat layer preferably has sufficient surface hardness while suppressing the occurrence of cracks in the laminate, even when the hard coat layer is formed on only one surface (one side) of the substrate. Moreover, the hard coat layer may be formed on both surfaces (both sides) of the substrate. However, in a case in which the laminate has the abovementioned tacky adhesive layer, the hard coat layer is preferably formed on only one surface of the substrate. Note that when the hard coat layer is formed on both surfaces of the substrate, the physical property values of the hard coat layer described below need only be satisfied on at least one surface. Furthermore, the same hard coat layer may be laminated on both surfaces of the substrate, or hard coat layers having different thicknesses or compositions may be laminated on respective surfaces of the substrate. In addition, the hard coat layer may be formed on one surface of the substrate, and another layer described above may be formed on the other surface. However, from the viewpoint of suppressing the occurrence of cracks, preferably, the hard coat layer is formed on at least one surface of the substrate, and the hard coat layer or an above-described other layer is formed on the other surface.

The hard coat layer is preferably formed of a cured product of a curable composition containing one or more curable compounds. That is, the curable composition preferably contains one or more types of curable compounds. A single type of curable compound may be used alone, or two or more types may be used in combination.

Examples of the curable compound include a (meth) acrylate compound, a curable silicone compound, an epoxy compound, a melamine compound, a vinyl ether compound, and an oxetane compound. Among these, the curable composition preferably contains a curable silicone compound, and more preferably contains silsesquioxane as the curable silicone compound, and particularly preferably contains a polyorganosilsesquioxane as the curable silicone compound. When the curable composition contains the polyorganosilsesquioxane, the curable composition is less likely to shrink during curing, and thus a hard coat layer having more excellent wear resistance can thereby be produced. Examples of the silsesquioxane include a radically polymerizable silsesquioxane and a cationically polymerizable silsesquioxane. Among these, the silsesquioxane is preferably a cationically polymerizable silsesquioxane, and the cationically polymerizable silsesquioxane is more preferably a photocationically polymerizable silsesquioxane.

The radically polymerizable silsesquioxane has a radically polymerizable functional group in the molecule. Examples of the “radically polymerizable functional group” include a (meth)acryloyl group, a (meth)acrylamide group, a vinyl group, and a vinylthio group.

The cationically polymerizable silsesquioxane has a cationically polymerizable functional group in the molecule. Examples of the “cationically polymerizable functional group” include an epoxy group, an oxetane group, a vinyl ether group, and a vinyl phenyl group. Among these, an epoxy group is preferable from the viewpoint of further increasing the surface hardness of the hard coat layer.

The group containing an epoxy group is not particularly limited, and examples thereof include well-known or commonly-used groups having an oxirane ring. However, in terms of curability of the curable composition and heat resistance of the hard coat layer, a group represented by Formula (1a) below, a group represented by Formula (1b) below, a group represented by Formula (1c) below, and a group represented by Formula (1d) below are preferred, a group represented by Formula (1a) below and a group represented by Formula (1c) below are more preferred, and a group represented by Formula (1a) below is even more preferred.

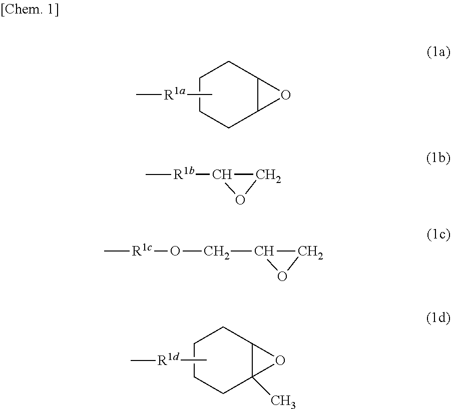

In Formula (1a) above, R^{1a} represents a linear or branched alkylene group. Examples of the linear or branched alkylene group include linear or branched alkylene groups having from 1 to 10 carbons, such as a methylene group, a methyl methylene group, a dimethyl methylene group, an ethylene group, a propylene group, a trimethylene group, a tetramethylene group, a pentamethylene group, a hexamethylene group, and a decamethylene group. Among these, from the viewpoint of the curability of the curable composition, R^{1a} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1b) above, R^{1b} represents a linear or branched alkylene group, and examples thereof include the same groups listed as examples of R^{1a}. Among these, from the viewpoint of the curability of the curable composition, R^{1b} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1c) above, R^{1c} represents a linear or branched alkylene group, and examples thereof include the same groups listed as examples of R^{1a}. Among these, from the viewpoint of the curability of the curable composition, R^{1c} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

In Formula (1d) above, R^{1d} represents a linear or branched alkylene group, and examples thereof include the same groups listed as examples of R^{1a}. Among these, from the viewpoint of the curability of the curable composition, R^{1d} is preferably a linear alkylene group having from 1 to 4 carbons or a branched alkylene group having 3 or 4 carbons, more preferably an ethylene group, a trimethylene group, or a propylene group, and even more preferably an ethylene group or a trimethylene group.

R¹ in Formula (1) is particularly preferably a group represented by Formula (1a) above in which R^{1a} is an ethylene group (especially, a 2-(3,4-epoxycyclohexyl)ethyl group).

Examples of the cationically polymerizable silsesquioxane include a compound having a constituent unit represented by Formula (1) below.

[R¹SiO_{3/2}] (1)

The constituent unit represented by Formula (1) above is a silsesquioxane constituent unit (so-called T unit) generally represented by [RSiO_{3/2}]. Here, R in the formula described above represents a hydrogen atom or a monovalent organic group, and the same shall apply hereafter. The constituent unit represented by Formula (1) above is formed by a hydrolysis and condensation reaction of a corresponding hydrolyzable trifunctional silane compound. Note that in the present specification, a compound having a constituent unit represented by the above Formula (1) may be referred to as a “silsesquioxane (X)”. R¹ in Formula (1) represents a group (monovalent group) containing the above-described cationically polymerizable functional group.

The silsesquioxane (X) may include only one type of constituent unit represented by Formula (1) above or may include two or more types of constituent units represented by Formula (1) above.

The silsesquioxane (X) may also include, as the silsesquioxane constituent unit [RSiO_{3/2}], a constituent unit represented by Formula (2) below, in addition to the constituent unit represented by Formula (1) above.

[R²SiO_{3/2}] (2)

The constituent unit represented by Formula (2) above is a silsesquioxane constituent unit (T unit) generally represented by [RSiO_{3/2}]. That is, the constituent unit represented by Formula (2) above is formed by a hydrolysis and condensation reaction of a corresponding hydrolyzable trifunctional silane compound.

R² in Formula (2) represents a substituted or unsubstituted aryl group, a substituted or unsubstituted aralkyl group, a substituted or unsubstituted cycloalkyl group, or a substituted or unsubstituted alkyl group. Examples of the aryl group include a phenyl group, a tolyl group, and a naphthyl group. Examples of the aralkyl group include a benzyl group and a phenethyl group. Examples of the cycloalkyl group include a cyclobutyl group, a cyclopentyl group, and a cyclohexyl group. Examples of the alkyl group include linear or branched alkyl groups, such as a methyl group, an ethyl group, a propyl group, an n-butyl group, an isopropyl group, an isobutyl group, an s-butyl group, a t-butyl group, and an isopentyl group.

Examples of the substituted aryl group, the substituted aralkyl group, the substituted cycloalkyl group, and the substituted alkyl group described above include groups in which some or all of hydrogen atoms or the main chain skeleton in each of the aryl groups, the aralkyl groups, the cycloalkyl groups, and the alkyl groups described above are substituted with at least one selected from the group consisting of an alkyl group (in particular, a linear or branched alkyl group having from 1 to 10 carbons), an ether group, an ester group, a carbonyl group, a siloxane group, a halogen atom (such as a fluorine atom), a mercapto group, an amino group, and a hydroxyl group.

Among these, R² is preferably a substituted or unsubstituted aryl group or a substituted or unsubstituted alkyl group, more preferably a substituted or unsubstituted aryl group, and even more preferably a phenyl group.

A ratio of each above-described silsesquioxane constituent unit (the constituent unit represented by Formula (1) and the constituent unit represented by Formula (2)) in the silsesquioxane (X) can be appropriately adjusted by the composition of the raw materials (hydrolyzable trifunctional silanes) for forming these constituent units.

Among these constituent units, the silsesquioxane (X) preferably contains at least a constituent unit represented by the above Formula (1) in which R¹ is a group containing an alicyclic epoxy group and a constituent unit represented by the above Formula (2) in which R² is an aryl group which may have a substituent. In this case, the surface hardness, flexibility, processability, and flame retardancy of the hard coat layer tend to be more excellent.

In addition to the constituent unit represented by Formula (1) above and the constituent unit represented by Formula (2) above, which are T units, the silsesquioxane (X) may further contain at least one siloxane constituent unit selected from the group consisting of a constituent unit represented by [R₃SiO_{1/2}] (so-called M unit), a constituent unit represented by [R₂SiO_{2/2}] (so-called D unit), and a constituent unit represented by [SiO_{4/2}] (so-called Q unit). Note that examples of R in the M unit and the D unit include the same groups as those exemplified as R¹ in the constituent unit represented by Formula (1) and those exemplified as R² in the constituent unit represented by Formula (2). An example of a silsesquioxane constituent unit other than the constituent unit represented by Formula (1) above and the constituent unit represented by Formula (2) above include a constituent unit represented by Formula (3) below.

[HSiO_{3/2}] (3)

The silsesquioxane (X) includes a constituent unit (T3 form) represented by Formula (I) below. The silsesquioxane (X) may further include a constituent unit (T2 form) represented by Formula (II) below.

[R^{a}SiO_{3/2}] (I)

[R^{b}SiO_{2/2}(OR^{c})] (II)

The constituent unit represented by Formula (I) above is represented by Formula (I′) below in more detail. Furthermore, the constituent unit represented by Formula (II) above is represented by Formula (II′) below in more detail. Three oxygen atoms bonded to the silicon atom illustrated in the structure represented by formula (I′) below are each bonded to another silicon atom (a silicon atom not illustrated in formula (I′)). On the other hand, two oxygen atoms located above and below the silicon atom illustrated in the structure represented by Formula (II′) below are each bonded to another silicon atom (a silicon atom not illustrated in Formula (II′)). That is, both T3 form and T2 form are constituent units (T units) formed by a hydrolysis and condensation reaction of a corresponding hydrolyzable trifunctional silane compound.

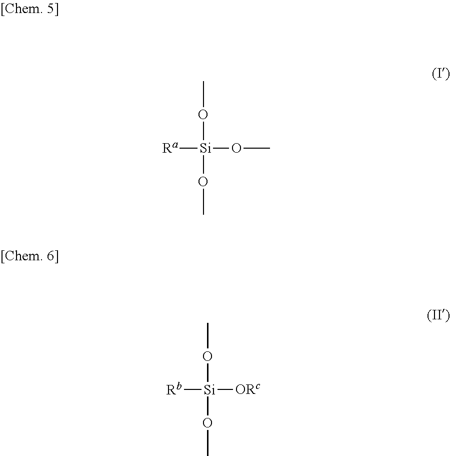

R^{a} in Formula (I) above (likewise, R^{a} in Formula (I′)) and R^{b} in Formula (II) above (likewise, R^{b} in Formula (II′)) each represent a group containing a cationically polymerizable functional group, a substituted or unsubstituted aryl group, a substituted or unsubstituted aralkyl group, a substituted or unsubstituted cycloalkyl group, a substituted or unsubstituted alkyl group, or a hydrogen atom. Specific examples of R^{a} and R^{b} include the same examples as those given for R¹ in Formula (1) above and R² in Formula (2) above. R^{a} in Formula (I) and R^{b} in Formula (II) are each a group derived from a group (a group other than an alkoxy group and a halogen atom) bonded to a silicon atom in the hydrolyzable trifunctional silane compound used as a raw material of the silsesquioxane (X), or, in a case in which the cationically polymerizable functional group is an epoxy group, a group produced by epoxidizing a group (a group other than an alkoxy group and a halogen atom) bonded to a silicon atom in the hydrolyzable trifunctional silane compound used as a raw material of the silsesquioxane (X).

R^{c} in Formula (II) above (likewise, R^{c} in Formula (II′)) represents a hydrogen atom or an alkyl group having from 1 to 4 carbons. Examples of the alkyl group having from 1 to 4 carbons include a linear or branched alkyl group having from 1 to 4 carbons, such as a methyl group, an ethyl group, a propyl group, an isopropyl group, a butyl group, and an isobutyl group. Among these, a methyl group and an ethyl are preferable, and a methyl group is more preferable. The alkyl group of R^{c} in Formula (II) is typically derived from an alkyl group that forms an alkoxy group in a hydrolyzable silane compound used as a raw material for the silsesquioxane (X).

In the silsesquioxane (X), a molar ratio of the constituent units represented by Formula (I) above (T3 forms) to the constituent units represented by Formula (II) above (T2 forms), [constituent units represented by Formula (I)/constituent units represented by Formula (II)] (may be described as “T3 form/T2 form”), is not particularly limited, but is preferably 5 or greater, more preferably from 5 to 20, even more preferably from 5 to 18, yet even more preferably from 6 to 16, still more preferably from 7 to 15, and particularly preferably from 8 to 14. When the above [(T3 form)/(T2 form)] molar ratio is 5 or greater, the surface hardness of the hard coat layer tends to further improve.

The above molar ratio [T3 form/T2 form] in the silsesquioxane (X) can be determined, for example, through ²⁹Si-NMR spectrum measurements. In the ²⁹Si-NMR spectrum, the silicon atoms in the constituent units represented by Formula (I) above (T3 forms) and the silicon atoms in the constituent units represented by Formula (II) above (T2 forms) exhibit signals (peaks) at different positions (chemical shifts), and thus the above-mentioned [T3 form/T2 form] molar ratio can be determined by calculating the integration ratio of these peaks. Specifically, for example, when the silsesquioxane (X) includes a constituent unit represented by Formula (1) above in which R¹ is a 2-(3,4-epoxycyclohexyl)ethyl group, the signal of the silicon atom in the structure (T3 form) represented by Formula (I) above appears in a range from −64 to −70 ppm, and the signal of the silicon atom in the structure (T2 form) represented by Formula (II) above appears in a range from −54 to −60 ppm. Thus, in this case, the above molar ratio [T3 form/T2 form] can be determined by calculating the integration ratio of the signal (T3 form) in the range from −64 to −70 ppm and the signal (T2 form) in the range from −54 to −60 ppm.

The ²⁹Si-NMR spectrum of the silsesquioxane (X) can be measured, for example, with the following instrument and under the following conditions.

Measuring instrument: “JNM-ECA500NMR” (trade name, available from JEOL Ltd.)

Solvent: deuterochloroform

Cumulative number of times: 1800

Measurement temperature: 25° C.

When the above molar ratio [T3 form/T2 form] of the silsesquioxane (X) is 5 or greater, this means that a certain amount or more of the T2 forms are present relative to the T3 forms in the silsesquioxane (X). Examples of the T2 form include a constituent unit represented by Formula (4) below, a constituent unit represented by Formula (5) below, and a constituent unit represented by Formula (6) below. R¹ in Formula (4) below and R² in Formula (5) below are the same as the R¹ in Formula (1) above and the R² in Formula (2) above, respectively. R^{c} in Formulae (4) to (6) below represents a hydrogen atom or an alkyl group having from 1 to 4 carbons, in the same manner as R^{c} in Formula (II).

[R¹SiO_{2/2}(OR^{c})] (4)

[R²SiO_{2/2}(OR^{c})] (5)

[HSiO_{2/2}(OR^{c})] (6)

The cationically polymerizable silsesquioxane (in particular, the silsesquioxane (X)) may be a silsesquioxane having a cage shape (cage-type silsesquioxane). Examples of the cage-type silsesquioxane include a complete cage-type silsesquioxane and an incomplete cage-type silsesquioxane, and among these, an incomplete cage-type silsesquioxane is preferable.

Typically, a complete cage-type silsesquioxane is a polyorganosilsesquioxane constituted of a T3 form only, and no T2 form is present in the molecule. That is, a silsesquioxane having the above molar ratio [T3 form/T2 form] of 5 or greater and having one inherent absorption peak near 1100 cm⁻¹ in an FT-IR spectrum as described later suggests the inclusion of an incomplete cage-type silsesquioxane structure.

Whether the silsesquioxane (X) has a cage-type (incomplete cage-type) silsesquioxane structure can be confirmed by the FT-IR spectrum [refer to R. H. Raney, M. Itoh, A. Sakakibara and T. Suzuki, Chem. Rev. 95, 1409 (1995)]. Specifically, if the silsesquioxane (X) has one inherent absorption peak near 1100 cm⁻¹ without having inherent absorption peaks near 1050 cm⁻¹ and 1150 cm⁻¹ in the FT-IR spectrum, the silsesquioxane (X) can be identified as having a cage-type (incomplete cage-type) silsesquioxane structure. In contrast, a silsesquioxane (X) having inherent absorption peaks near 1050 cm⁻¹ and near 1150 cm⁻¹ each in the FT-IR spectrum is typically identified as having a ladder-type silsesquioxane structure. The FT-IR spectrum of the silsesquioxane (X) can be measured, for example, with the following instrument and conditions.

Measuring instrument: trade name “FT-720” (available from Horiba, Ltd.)

Measurement method: transmission method

Resolution: 4 cm⁻¹

Measurement wavenumber range: from 400 to 4000 cm⁻¹

Cumulative number of times: 16

The proportion (total amount) of the constituent unit having the cationically polymerizable functional group (for example, the constituent unit represented by Formula (1) above, the constituent unit represented by Formula (4) above, and the like) relative to a total amount (100 mol %) of siloxane constituent units [all siloxane constituent units; total amount of M units, D units, T units, and Q units] in the cationically polymerizable silsesquioxane is not particularly limited, but is preferably 50 mol % or greater (for example, from 50 to 100 mol %), more preferably from 55 to 100 mol %, even more preferably from 65 to 99.9 mol %, yet even more preferably from 80 to 99 mol %, and particularly preferably from 90 to 98 mol %. When the above proportion is set to 50 mol % or greater, the curability of the curable composition improves, or the surface hardness of the hard coat layer significantly increases. In addition, the proportion of each siloxane constituent unit in the cationically polymerizable silsesquioxane can be calculated, for example, from the raw material composition through NMR spectrum measurements, or the like.

The proportion of the constituent unit (T3 form) represented by Formula (I) above relative to the total amount (100 mol %) of siloxane constituent units [all siloxane constituent units; total amount of M units, D units, T units, and Q units] in the silsesquioxane (X) is not particularly limited, but is preferably 50 mol % or greater, more preferably from 60 to 99 mol %, even more preferably from 70 to 98 mol %, yet even more preferably from 80 to 95 mol %, and particularly preferably from 85 to 92 mol %. When the proportion of the constituent unit of the T3 form is 50 mol % or greater, the surface hardness of the hard coat layer tends to further improve. This is presumed to be due to a facilitation of the formation of an incomplete cage shape having an appropriate molecular weight.

The proportion (total amount) of the constituent unit represented by Formula (2) above and the constituent unit represented by Formula (5) above relative to the total amount (100 mol %) of siloxane constituent units [all siloxane constituent units; total amount of M units, D units, T units, and Q units] in the silsesquioxane (X) is not particularly limited, but is preferably from 0 to 50 mol %, more preferably from 0 to 40 mol %, even more preferably from 0 to 30 mol %, and particularly preferably from 1 to 15 mol %. When the above ratio is set to 50 mol % or less, the proportion of the constituent unit having a cationically polymerizable functional group can be relatively increased, and thus such a ratio tends to improve the curability of the curable composition and further increase the surface hardness of the hard coat layer.

The proportion (total amount) of the constituent unit represented by Formula (I) above and the constituent unit represented by Formula (II) above (in particular, the proportion of the total of T3 forms and T2 forms) relative to the total amount (100 mol %) of siloxane constituent units [all siloxane constituent units; total amount of M units, D units, T units, and Q units] in the silsesquioxane (X) is not particularly limited, but is preferably 60 mol % or greater (for example, from 60 to 100 mol %), more preferably from 70 mol % or greater, even more preferably from 80 mol % or greater, and particularly preferably from 90 mol % or greater. When the above proportion is 60 mol % or greater, the surface hardness of the hard coat layer tends to further improve. This is presumed to be due to a facilitation of the formation of an incomplete cage shape having an appropriate molecular weight. In particular, the proportion (total amount) of the constituent unit represented by the Formula (1) above, the constituent unit represented by the Formula (2) above, the constituent unit represented by the Formula (4) above, and the constituent unit represented by the Formula (5) above is preferably within the above range.

The number average molecular weight (Mn) of the silsesquioxane (X) determined by gel permeation chromatography and calibrated with polystyrene is not particularly limited, but is preferably from 1000 to 3000, more preferably from 1000 to 2800, even more preferably from 1100 to 2600, and particularly preferably from 1500 to 2500. When the number average molecular weight is 1000 or greater, the surface hardness of the hard coat layer tends to further improve. Alternatively, the heat resistance and wear resistance of the hard coat layer tend to be improved. On the other hand, when the number average molecular weight is 3000 or less, the compatibility with other components in the curable composition tends to improve and the heat resistance of the hard coat layer tends to improve.

The molecular weight dispersity (Mw/Mn) of the silsesquioxane (X) determined by gel permeation chromatography and calibrated with polystyrene is not particularly limited, but is preferably from 1.0 to 3.0, more preferably from 1.1 to 2.0, even more preferably from 1.2 to 1.9, yet even more preferably from 1.3 to 1.8, and particularly preferably from 1.45 to 1.80. When the molecular weight dispersity is 3.0 or less, the surface hardness of the hard coat layer tends to further increase. On the other hand, when the molecular weight dispersity is 1.0 or greater (in particular, 1.1 or greater), the silsesquioxane (X) tends to easily become a liquid, and handling ease tends to improve.

The number average molecular weight and the molecular weight dispersity of the silsesquioxane (X) can be measured with the following instrument and conditions.

Measuring instrument: “LC-20AD” (trade name, available from Shimadzu Corporation)

Column: Shodex KF-801×quantity of 2, KF-802, and KF-803 (available from Showa Denko K.K.)

Measurement temperature: 40° C.

Eluent: THE, sample concentration of from 0.1 to 0.2 mass %

Flow rate: 1 mL/min

Detector: UV-VIS detector (“SPD-20A” (trade name) available from Shimadzu Corporation)

Molecular weight: calibrated with standard polystyrene

The method for producing the cationically polymerizable silsesquioxane is not particularly limited, and the cationically polymerizable silsesquioxane can be produced by a well-known or commonly used silsesquioxane production method. Examples include a method of subjecting one or more types of hydrolyzable silane compounds to hydrolysis and condensation.

The content proportion of the polyorganosilsesquioxane in the curable composition is not particularly limited, but relative to the total amount (100 mass %) of the curable compounds, the content of the polyorganosilsesquioxane therein is preferably greater than 50 mass % (for example, greater than 50 mass % and less than or equal to 98 mass %), more preferably from 60 to 96 mass %, even more preferably from 70 to 95 mass %, and particularly preferably from 80 to 93 mass %. When the content proportion thereof is greater than 50 mass %, the surface hardness of the hard coat layer tends to further improve. When the above content proportion is 98 mass % or less, other components can be blended, and the effects provided by blending these components tend to further improve. Moreover, a curing catalyst can be blended, and thereby curing of the curable composition tends to proceed more efficiently.

The curable composition preferably includes a compound (hereinafter, also referred to as a “compound (A)”) having one or more cationically polymerizable groups and one or more radically polymerizable groups per molecule. When the curable composition contains the compound (A), the crosslinking density when the curable composition is formed into a cured product can be effectively increased, a high surface hardness and excellent bendability and bending durability are more easily imparted to the hard coat layer, and antifouling performance is less likely to be reduced. Note that a single type of the compound (A) may be used alone, or two or more types may be used in combination.

Examples of the “cationically polymerizable group” of the compound (A) include an epoxy group, an oxetanyl group, a vinyl ether group, and a hydroxyl group, and an epoxy group is preferable from the viewpoint of suppressing a decrease in surface hardness, bendability, and bending durability of the hard coat layer. Note that when the compound (A) has two or more cationically polymerizable groups, these cationically polymerizable groups may each be the same or different.

Examples of the “radically polymerizable group” of the compound (A) include a (meth)acryloyl group and a vinyl group, and from the viewpoint of the surface hardness and bending durability of the hard coat layer, a (meth)acryloyl group is preferable. Note that when the compound (A) has two or more radically polymerizable groups, these radically polymerizable groups may each be the same or different.

The number of the cationically polymerizable groups per molecule of the compound (A) is not particularly limited as long as the number thereof is 1 or greater, but is preferably from 1 to 5, more preferably from 1 to 3, and even more preferably 1 or 2. In addition, the number of the radically polymerizable groups per molecule of the compound (A) is not particularly limited as long as the number thereof is 1 or greater, but for example, the number thereof is preferably from 1 to 5, more preferably from 1 to 3, and even more preferably 1 or 2.

The functional group equivalent of the cationically polymerizable group of the compound (A) is not particularly limited, but is preferably from 50 to 500, more preferably from 80 to 480, and even more preferably from 120 to 450. When the above functional group equivalent is 50 or greater, sufficient bending durability of the hard coat layer can be easily achieved. When the above functional group equivalent is 500 or less, sufficient surface hardness of the hard coat layer can be achieved. Note that the functional group equivalent of the cationically polymerizable group of the compound (A) can be calculated from the following equation.

[Functional group equivalent of cationically polymerizable group]=[molecular weight of compound (A)]/[number of cationically polymerizable groups in compound (A)]

The functional group equivalent of the radically polymerizable group of the compound (A) is not particularly limited, but is preferably from 50 to 500, more preferably from 80 to 480, and even more preferably from 120 to 450. When the above functional group equivalent is 50 or greater, sufficient bending durability of the hard coat layer can be easily achieved. When the above functional group equivalent is 500 or less, sufficient surface hardness of the hard coat layer can be achieved. Note that the functional group equivalent of the radically polymerizable group of the compound (A) can be calculated from the following equation.

[Functional group equivalent of radically polymerizable group]=[molecular weight of compound (A)]/[number of radically polymerizable groups in compound (A)]

Specific examples of the compound (A) include compounds having an epoxy group and a (meth)acryloyl group per molecule, such as 3,4-epoxycyclohexylmethyl (meth)acrylate, glycidyl (meth)acrylate, tripropylene glycol diglycidyl ether di(meth)acrylate (a compound produced by reacting (meth)acrylic acid with both epoxy groups of tripropylene glycol diglycidyl ether), tripropylene glycol diglycidyl ether half (meth)acrylate (a compound produced by reacting (meth)acrylic acid with one epoxy group of tripropylene glycol diglycidyl ether), bisphenol A epoxy (meth)acrylate (a compound produced by reacting (meth)acrylic acid with both epoxy groups of bisphenol A diglycidyl ether), bisphenol A epoxy half (meth)acrylate (a compound produced by reacting (meth)acrylic acid or a derivative thereof with one epoxy group of bisphenol A diglycidyl ether), bisphenol F epoxy di(meth)acrylate, bisphenol F epoxy half (meth)acrylate, bisphenol S epoxy di(meth)acrylate, and bisphenol S epoxy half (meth)acrylate; compounds having an oxetanyl group and a (meth)acryloyl group per molecule, such as 3-oxetanyl methyl(meth)acrylate, 3-methyl-3-oxetanyl methyl(meth)acrylate, 3-ethyl-3-oxetanyl methyl(meth)acrylate, 3-butyl-3-oxetanyl methyl(meth)acrylate, and 3-hexyl-3-oxetanyl methyl (meth)acrylate; and compounds having a vinyl ether group and a (meth)acryloyl group per molecule, such as 2-vinyloxy ethyl (meth)acrylate, 3-vinyloxy propyl (meth)acrylate, 1-methyl-2-vinyloxy ethyl (meth)acrylate, 2-vinyloxy propyl (meth)acrylate, 4-vinyloxy butyl (meth)acrylate, 1-methyl-3-vinyloxy propyl (meth)acrylate, 1-vinyloxy methylpropyl (meth)acrylate, 2-methyl-3-vinyloxy propyl (meth)acrylate, 1,1-dimethyl-2-vinyloxy ethyl (meth)acrylate, 3-vinyloxy butyl (meth)acrylate, 1-methyl-2-vinyloxy propyl (meth)acrylate, 2-vinyloxy butyl (meth)acrylate, 4-vinyloxy cyclohexyl (meth)acrylate, 6-vinyloxy hexyl (meth)acrylate, 4-vinyloxy methylcyclohexyl methyl (meth)acrylate, 3-vinyloxy methylcyclohexyl methyl (meth)acrylate, 2-vinyloxy cyclohexyl methyl (meth)acrylate, p-vinyloxy methylphenyl methyl (meth)acrylate, m-vinyloxy methylphenyl methyl (meth)acrylate, o-vinyloxy methylphenyl methyl (meth)acrylate, 2-(vinyloxyethoxy)ethyl (meth)acrylate, 2-(vinyloxyisopropoxy)ethyl (meth)acrylate, 2-(vinyloxyethoxy)propyl (meth)acrylate, 2-(vinyloxyethoxy)isopropyl (meth)acrylate, 2-(vinyloxyisopropoxy)propyl (meth)acrylate, 2-(vinyloxyisopropoxy)isopropyl (meth)acrylate, 2-(vinyloxyethoxyethoxy)ethyl (meth)acrylate, 2-(vinyloxyethoxyisopropoxy)ethyl (meth)acrylate, 2-(vinyloxyisopropoxyethoxy)ethyl (meth)acrylate, 2-(vinyloxyisopropoxyisopropoxy)ethyl (meth)acrylate, 2-(vinyloxyethoxyethoxy)propyl (meth)acrylate, 2-(vinyloxyethoxyisopropoxy)propyl (meth)acrylate, 2-(vinyloxyisopropoxyethoxy)propyl (meth)acrylate, 2-(vinyloxyisopropoxyisopropoxy)propyl (meth)acrylate, 2-(vinyloxyethoxyethoxy)isopropyl (meth)acrylate, 2-(vinyloxyethoxyisopropoxy)isopropyl (meth)acrylate, 2-(vinyloxyisopropoxyethoxy)isopropyl (meth)acrylate, 2-(vinyloxyisopropoxyisopropoxy)isopropyl (meth)acrylate, 2-(vinyloxyethoxyethoxyethoxy)ethyl (meth)acrylate, 2-(vinyloxyethoxyethoxyethoxyethoxy)ethyl (meth)acrylate, 2-(isopropenoxyethoxy)ethyl (meth)acrylate, 2-(isopropenoxyethoxyethoxy)ethyl (meth)acrylate, 2-(isopropenoxyethoxyethoxyethoxy)ethyl (meth)acrylate, 2-(isopropenoxyethoxyethoxyethoxyethoxy)ethyl (meth)acrylate, polyethylene glycol monovinyl ether (meth)acrylate, and polypropylene glycol monovinyl ether (meth)acrylate.

From the perspective of the bending durability and surface hardness of the hard coat layer, the compound (A) is preferably a compound having, per molecule, an epoxy group as a cationically polymerizable group and a (meth)acryloyl group as a radically polymerizable group, and specifically, 3,4-epoxycyclohexylmethyl (meth)acrylate, glycidyl (meth)acrylate, tripropylene glycol diglycidyl ether half (meth)acrylate, bisphenol A epoxy half (meth)acrylate, bisphenol F epoxy half (meth)acrylate, and bisphenol S epoxy half (meth)acrylate are preferable.

The compound (A) can be produced by a known method, for example, by a method of reacting some of cationically polymerizable groups of a compound having two or more cationically polymerizable groups (for example, epoxy groups) per molecule with a carboxylic acid (for example, acrylic acid or methacrylic acid) having a radically polymerizable group, or with a derivative thereof. Furthermore, commercially available products such as products of the trade names “Light Ester G”, “Epoxy Ester 200PA”, and “Epoxy Ester 200PA-E5” (the above are available from Kyoeisha Chemical Co., Ltd.), and a product of the trade name “NK OLIGO EA1010N” (available from Shin-Nakamura Chemical Co., Ltd.) may also be used as the compound (A).

The content proportion of the compound (A) in the curable composition is not particularly limited, but in relation to the total amount (100 mass %) of the curable compound, the content of the compound (A) is preferably from 0.05 to 8 mass %, more preferably from 0.1 to 5 mass %, and even more preferably from 0.2 to 3 mass %. When the content proportion of the compound (A) is within the above range, the sebum adhesion resistance of the hard coat layer is more excellent.

The content (blended amount) of the compound (A) in the curable composition is not particularly limited, but as a solid content relative to 100 parts by mass of the polyorganosilsesquioxane, the content of the compound (A) is preferably from 1 to 100 parts by mass, more preferably from 1.5 to 75 parts by mass, and even more preferably from 2 to 50 parts by mass. When the content of the compound (A) is 1 part by mass or greater, the bendability and bending durability of the hard coat layer tend to further improve. On the other hand, when the content of the compound (A) is 100 parts by mass or less, the surface hardness of the hard coat layer tends to be maintained.

In addition, the curable composition preferably contains an aliphatic compound (hereinafter, may be referred to as a compound (B)) having two or more cationically polymerizable groups per molecule. When the curable composition contains the compound (B), the curable composition can impart flexibility to the hard coat layer, and bending and bending durability can be easily exhibited. The compound (B) is a compound that does not correspond to the polyorganosilsesquioxane or to the compound (A). A single type of the compound (B) may be used alone, or two or more types may be used in combination.

Examples of the cationically polymerizable group include the same groups as those exemplified for the compound (A). Examples thereof include an epoxy group, an oxetanyl group, and a vinyl ether group, and from the viewpoint of exhibiting surface hardness, bendability, and bending durability of the hard coat layer, an epoxy group is preferable, whereas from the viewpoint of reactivity, a glycidyl group is more preferable. Note that the two or more cationically polymerizable groups of the compound (B) may be the same or different.

The number of the cationically polymerizable groups per molecule of the compound (B) is not particularly limited as long as the number thereof is 2 or greater, but for example, the number thereof is preferably from 2 to 5, more preferably 2 or 3, and even more preferably 2.

The functional group equivalent of the cationically polymerizable group of the compound (B) is not particularly limited, but is preferably from 50 to 500, more preferably from 80 to 480, and even more preferably from 120 to 450. When the above functional group equivalent is 50 or greater, sufficient bending durability of the hard coat layer can be easily achieved. When the above functional group equivalent is 500 or less, sufficient surface hardness of the hard coat layer can be achieved. Note that the functional group equivalent of the cationically polymerizable group of the compound (B) can be calculated from the following equation.

[Functional group equivalent of cationically polymerizable group]=[molecular weight of compound (B)]/[number of thermally polymerizable functional groups in compound (B)]

The “aliphatic compound” in the compound (B) is an aliphatic compound having no cyclic structure other than the cationically polymerizable group. Examples of the compound (B) include a glycidyl ether of a dihydric or higher alcohol having no cyclic structure; and a glycidyl ester of a divalent or higher carboxylic acid [such as, for example, adipic acid, sebacic acid, maleic acid, and itaconic acid]. Here, examples of the dihydric or higher alcohol having no cyclic structure include dihydric alcohols, such as ethylene glycol, 1,2-propanediol, 1,3-propanediol, 1,4-butanediol, neopentyl glycol, 1,6-hexanediol, diethylene glycol, triethylene glycol, tetraethylene glycol, dipropylene glycol, polyethylene glycol, and polypropylene glycol; and trihydric or higher polyhydric alcohols, such as glycerin, diglycerin, erythritol, trimethylolethane, trimethylolpropane, pentaerythritol, dipentaerythritol, and sorbitol. In addition, the dihydric or higher alcohol may be a polyether polyol, a polyester polyol, a polycarbonate polyol, a polyolefin polyol, or the like.

Moreover, the compound (B) is preferably a compound having a cationically polymerizable group at both ends thereof, and specifically, is preferably an aliphatic glycidyl ether-type epoxy compound.

Examples of the aliphatic glycidyl ether-type epoxy compound include a (poly) alkylene glycol diglycidyl ether such as ethylene glycol diglycidyl ether, diethylene glycol diglycidyl ether, and triethylene glycol diglycidyl ether; and a diol diglycidyl ether such as 1,6-hexanediol diglycidyl ether. Examples of commercially available products of the aliphatic glycidyl ether-type epoxy compound include products of the trade names “Epolight 40E”, “Epolight 100E”, “Epolight 200E”, “Epolight 400E”, and “Epolight 1600N” (available from Kyoeisha Chemical Co., Ltd.), and product of the trade name “YH-300” (available from Nippon Steel Chemical & Material Co., Ltd.).

The content proportion of the compound (B) in the curable composition is not particularly limited, but in relation to the total amount (100 mass %) of the curable compounds, the content of the compound (B) is preferably from 1 to 20 mass %, more preferably from 2 to 15 mass %, and even more preferably from 3 to 10 mass %. When the content proportion thereof is within the above range, the flexibility and bending resistance of the hard coat layer become more appropriate.

The content of the compound (B) is not particularly limited, but in relation to 100 parts by mass of the polyorganosilsesquioxane, the content of the compound (B) is preferably from 1 to 20 parts by mass, more preferably from 2 to 15 parts by mass, and even more preferably from 3 to 10 parts by mass. When the content thereof is within the above range, the bendability and bending resistance of the hard coat layer becomes more appropriate.

The curable composition preferably contains a curing catalyst. The curing catalyst is a compound that can initiate and promote polymerization reactions of the curable compounds such as the polyorganosilsesquioxane, the compound (A), and the compound (B). A single type of the above curing catalyst may be used alone, or two or more types may be used in combination.

The curing catalyst is selected according to the types of the curable functional groups of the curable compounds, and among the different types of curing catalysts, a cationic polymerization initiator and/or a radical polymerization initiator is preferable. The cationic polymerization initiator is a compound that generates a cationic species in response to heat or irradiation with active energy rays, and thereby initiates a curing reaction of the curable compounds.

Examples of the cationic polymerization initiator include a photocationic polymerization initiator (a photo acid generating agent) and a thermal cationic polymerization initiator (a thermal acid generating agent).

Known or commonly used photocationic polymerization initiators can be used as the photocationic polymerization initiator, and examples thereof include a sulfonium salt (a salt of a sulfonium ion and an anion), an iodonium salt (a salt of an iodonium ion and an anion), a selenium salt (a salt of a selenium ion and an anion), an ammonium salt (a salt of an ammonium ion and an anion), a phosphonium salt (a salt of a phosphonium ion and an anion), and a salt of a transition metal complex ion and an anion.

Examples of the sulfonium salt include a triarylsulfonium salt, such as a triphenylsulfonium salt, a tri-p-tolylsulfonium salt, a tri-o-tolylsulfonium salt, a tris(4-methoxyphenyl)sulfonium salt, a 1-naphthyldiphenylsulfonium salt, a 2-naphthyldiphenylsulfonium salt, a tris(4-fluorophenyl)sulfonium salt, a tri-1-naphthylsulfonium salt, a tri-2-naphthylsulfonium salt, a tris(4-hydroxyphenyl)sulfonium salt, a diphenyl[4-(phenylthio)phenyl]sulfonium salt, a 4-(p-tolylthio)phenyldi-(p-phenyl)sulfonium salt; a diarylsulfonium salt, such as a diphenylphenacylsulfonium salt, a diphenyl 4-nitrophenacylsulfonium salt, a diphenylbenzylsulfonium salt, and a diphenylmethylsulfonium salt; a monoarylsulfonium salt, such as a phenylmethylbenzylsulfonium salt, a 4-hydroxyphenylmethylbenzylsulfonium salt, and a 4-methoxyphenylmethylbenzyl sulfonium salt; and a trialkyl sulfonium salt, such as a dimethylphenacyl sulfonium salt, a phenacyl tetrahydrothiophenium salt, and a dimethyl benzylsulfonium salt.

Examples of the diphenyl [4-(phenylthio)phenyl]sulfonium salt include diphenyl[4-(phenylthio)phenyl]sulfonium tetrakis(pentafluorophenyl) borate and diphenyl[4-(phenylthio)phenyl] sulfonium hexafluorophoshate. Furthermore, commercially available products such as “CPI-100P” (trade name, diphenyl[4-(phenylthio)phenyl] sulfonium hexafluorophosphate in 50% propylene carbonate solution, available from San-Apro Ltd.) can also be used.

Examples of the iodonium salt include the “Rhodorsil Photoinitiator 2074” (trade name, tetrakis(pentafluorophenyl)borate·[(1-methylethyl)phenyl](methylphenyl)iodonium, available from Rhodia Japan Ltd.), “WPI-124” (trade name, available from Wako Pure Chemical Industries, Ltd.), a diphenyliodonium salt, a di-p-tolyliodonium salt, a bis(4-dodecylphenyl)iodonium salt, and a bis(4-methoxyphenyl)iodonium salt.

Examples of the selenium salt include a triarylselenium salt, such as a triphenylselenium salt, a tri-p-tolylselenium salt, a tri-o-tolylselenium salt, a tris(4-methoxyphenyl)selenium salt, and a 1-naphthyldiphenylselenium salt; a diarylselenium salt, such as a diphenylphenacylselenium salt, a diphenylbenzylselenium salt, and a diphenylmethylselenium salt; a monoarylselenium salt, such as a phenylmethylbenzylselenium salt; and a trialkylselenium salt, such as a dimethylphenacylselenium salt.

Examples of the ammonium salt include a tetraalkyl ammonium salt, such as a tetramethyl ammonium salt, an ethyltrimethyl ammonium salt, a diethyldimethyl ammonium salt, a triethylmethyl ammonium salt, a tetraethyl ammonium salt, a trimethyl-n-propyl ammonium salt, and a trimethyl-n-butyl ammonium salt; a pyrrolidium salt, such as an N,N-dimethylpyrrolidium salt and an N-ethyl-N-methylpyrrolidium salt; an imidazolinium salt, such as an N,N′-dimethylimidazolinium salt and an N,N′-diethylimidazolinium salt; a tetrahydropyrimidium salt, such as an N,N′-dimethyltetrahydropyrimidium salt and an N,N′-diethyltetrahydropyrimidium salt; a morpholinium salt, such as an N,N-dimethylmorpholinium salt and an N,N-diethylmorpholinium salt; a piperidinium salt, such as an N,N-dimethylpiperidinium salt and an N,N-diethylpiperidinium salt; a pyridinium salt, such as an N-methylpyridinium salt and an N-ethylpyridinium salt; an imidazolium salt, such as an N,N′-dimethylimidazolium salt; a quinolium salt, such as an N-methylquinolium salt; an isoquinolium salt, such as an N-methylisoquinolium salt; a thiazonium salt, such as a benzylbenzothiazonium salt; and an acrydium salt, such as a benzylacrydium salt.

Examples of the phosphonium salt include a tetra-arylphosphonium salt, such as a tetra-phenylphosphonium salt, a tetra-p-tolylphosphonium salt, and a tetrakis(2-methoxyphenyl)phosphonium salt; a triarylphosphonium salt, such as a triphenylbenzylphosphonium salt; and a tetra-alkylphosphonium salt, such as a triethylbenzylphosphonium salt, a tributylbenzylphosphonium salt, a tetra-ethylphosphonium salt, a tetra-butylphosphonium salt, and a triethylphenacylphosphonium salt.

Examples of the salt of a transition metal complex ion include a salt of a chromium complex cation, such as (η⁵-cyclopentadienyl)(η⁶-toluene)Cr⁺ and (η⁵-cyclopentadienyl)(η⁶-xylene)Cr⁺; and a salt of an iron complex cation, such as (η⁵-cyclopentadienyl)(η⁶-toluene)Fe⁺ and (η⁵-cyclopentadienyl)(η⁶-xylene)Fe⁺.

Examples of anions constituting the above-described salts include PF₆⁻, BF₄⁻, (C₆F₅)₄B⁻, (C₆F₅)₄Ga⁻, a sulfonate anion (such as trifluoromethane sulfonate anion, pentafluoroethane sulfonate anion, methane sulfonate anion, benzene sulfonate anion, and p-toluene sulfonate anion), a perhalogenate ion, a halogenated sulfonate ion, sulfate ion, carbonate ion, aluminate ion, carboxylate ion, arylborate ion, thiocyanate ion, and nitrate ion.

Examples of the thermal cationic polymerization initiator include an arylsulfonium salt, an aryliodonium salt, an allene-ion complex, a quaternary ammonium salt, an aluminum chelate, and a boron trifluoride amine complex. Examples of anions constituting the above-described salts include the same examples as the anions of the photocationic polymerization initiators described above.

Examples of the arylsulfonium salt include pentafluorophenyl borate and hexafluorophosphate. In the curable composition according to an embodiment of the present disclosure, a commercially available product can be used, such as, for example, products of the trade names “SP-66” and “SP-77” (available from Adeka Corporation); and products of the trade names “SAN-AID SI-150L”, “SAN-AID SI-110”, “SAN-AID SI-360”, “SAN-AID SI-300”, “SAN-AID SI-B4”, “SAN-AID SI-B5”, “SAN-AID SI-B3”, “SAN-AID SI-B3A”, “SAN-AID SI-B7”, and “SAN-AID SI-B2A” (available from Sanshin Chemical Industry Co., Ltd.). Examples of the aluminum chelate include ethylacetoacetate aluminum diisopropylate and aluminum tris(ethylacetoacetate). Moreover, examples of the boron trifluoride amine complex include a boron trifluoride monoethyl amine complex, a boron trifluoride imidazole complex, and a boron trifluoride piperidine complex.

The radical polymerization initiator is a compound that generates radicals in response to heat or irradiation with active energy rays, and thereby initiates a curing reaction of the curable compound.

Examples of the radical polymerization initiator include a photoradical polymerization initiator and a thermal radical polymerization initiator. Examples of the photoradical polymerization initiator include an alkylphenone-based photoradical polymerization initiator, an acylphosphine oxide-based photoradical polymerization initiator, an oxime ester-based photoradical polymerization initiator, and an α-hydroxyketone-based photoradical polymerization initiator.

Examples of the alkylphenone-based photoradical polymerization initiator include oligomers of 2-hydroxy-2-methyl-1-phenylpropan-1-one, 2-benzyl-2-dimethylamino-1-(4-morpholinophenyl)-1-butanone, 2-(dimethylamino)-2-[(4-methylphenyl)methyl]-[4-(4-morpholinyl) phenyl]-1-butanone, 2-methyl-1-[4-(methylthio)phenyl]-2-morpholinopropan-1-one, benzophenone, methylbenzophenone, o-benzoylbenzoic acid, benzoylethyl ether, 2,2-diethoxyacetophenone, 2,4-diethylthioxanthone, diphenyl-(2,4,6-trimethylbenzoyl) phosphineoxide, ethyl-(2,4,6-trimethylbenzoyl) phenylphosphinate, 4,4′-bis(diethylamino)benzophenone, 1-hydroxycyclohexylphenyl ketone, 2,2-dimethoxy-1,2-diphenylethan-1-one, 1-[4-(2-hydroxyethoxy)phenyl]-2-hydroxy-2-methyl-1-propan-1-one, and 2-hydroxy-1-(4-isopropenylphenyl)-2-methylpropan-1-one.

Examples of the acylphosphine oxide-based photoradical polymerization initiators include 2,4,6-trimethylbenzoyl diphenylphosphine oxide and bis(2,4,6-trimethylbenzoyl) phenylphosphine oxide.

Examples of the oxime ester-based photoradical polymerization initiator include 1-[4-(phenylthio)phenyl]-1,2-octandione 2-(O-benzoyloxime) and 1-[6-(2-methylbenzoyl)-9-ethyl-9H-carbazol-3-yl]ethanone O-acetyloxime.

Examples of the α-hydroxyketone-based photoradical polymerization initiator include benzoin, benzoin methyl ether, benzoin butyl ether, 1-hydroxycyclohexylphenyl ketone, 1-phenyl-2-hydroxy-2-methylpropan-1-one, 1-(4-i-propylphenyl)-2-hydroxy-2-methylpropan-1-one, 4-(2-hydroxyethoxy) phenyl-(2-hydroxy-2-propyl) ketone, and 1-hydroxycyclohexylphenyl ketone.

The content (blending amount) of the curing catalyst in the curable composition is not particularly limited, but is preferably from 0.01 to 10 parts by mass, more preferably from 0.03 to 5 parts by mass, and still more preferably from 0.05 to 3 parts by mass, per 100 parts by mass of the total amount of the curable compounds. When the content of the curing catalyst is 0.01 parts by mass or greater, the curing reaction can be efficiently and sufficiently advanced, and the surface hardness of the hard coat layer tends to be further improved. On the other hand, when the content of the curing catalyst is 10 parts by mass or less, the storage properties of the curable composition tend to improve, and coloration of the cured product tends to be inhibited.

The content (blending amount) of the cationic polymerization initiator in the curable composition is not particularly limited, but is preferably from 0.005 to 10 parts by mass, more preferably from 0.01 to 5 parts by mass, still more preferably from 0.015 to 3 parts by mass, and particularly preferably from 0.02 to 2 parts by mass, per 100 parts by mass of the total amount of the curable compounds. When the content thereof is 0.005 parts by mass or greater, the curing reaction can be efficiently and sufficiently advanced, and the surface hardness of the resulting cured product tends to further improve. On the other hand, when the content thereof is 10 parts by mass or less, the storage properties of the curable composition tend to improve, and coloration of the cured product tends to be inhibited.

The content (blending amount) of the radical polymerization initiator in the curable composition is not particularly limited, but is preferably from 0.01 to 5 parts by mass, more preferably from 0.03 to 3 parts by mass, and still more preferably from 0.05 to 2 parts by mass, per 100 parts by mass of the total amount of the curable compounds. When the content thereof is 0.01 parts by mass or greater, the curing reaction can be efficiently and sufficiently advanced, and the surface hardness of the resulting cured product tends to further improve. On the other hand, when the content thereof is 5 parts by mass or less, the storage properties of the curable composition tend to improve, and coloration of the cured product tends to be inhibited.

The curable composition preferably contains a radically curable polyorganosiloxane as a leveling agent. Use of the radically curable polyorganosiloxane improves the smoothness of the surface of the hard coat layer, and enables bendability and bending durability to be exhibited. In addition, preferably, the radically curable polyorganosiloxane does not correspond to a PFAS. In this case, the above-described effects can be exhibited as long as the radically curable polyorganosiloxane does not correspond to a PFAS. A single type of the radically curable polyorganosiloxane may be used alone, or two or more types may be used in combination.

The radically curable polyorganosiloxane has a radically polymerizable functional group in the molecule. Examples of the radically curable functional group include a photoradically polymerizable functional group.

Examples of the photoradically polymerizable functional group include a (meth)acryloyl group, a (meth)acrylamide group, a vinyl group, and a vinylthio group. Among these, a (meth)acryloyl group is preferred.

The polyorganosiloxane in the radically curable polyorganosiloxane is preferably a linear polyorganosiloxane from the viewpoint of exhibiting a greater effect as a leveling agent.

The content of the radically curable polyorganosiloxane is not particularly limited, but in relation to 100 parts by mass of the polyorganosilsesquioxane, the content of the radically curable polyorganosiloxane is preferably from 0.01 to 5 parts by mass, more preferably from 0.03 to 3 parts by mass, and even more preferably from 0.05 to 2 parts by mass.

The curable composition preferably contains an antioxidant. When the curable composition contains an antioxidant, the storage properties of the hard coat layer tend to further improve. A single type of antioxidant may be used alone, or two or more types may be used in combination.

As the antioxidant, a well-known or commonly used antioxidant can be used, and examples thereof include, but are not particularly limited to, a phenol-based antioxidant, a hindered amine-based antioxidant, a phosphorus-based antioxidant, and a sulfur-based antioxidant.

Examples of the phenol-based antioxidant include monophenols such as 2,6-di-t-butyl-p-cresol, butylated hydroxyanisole, 2,6-di-t-butyl-p-ethylphenol, and stearyl-β-(3,5-di-t-butyl-4-hydroxyphenyl) propionate; bisphenols such as 2,2′-methylenebis(4-methyl-6-t-butylphenol), 2,2′-methylenebis(4-ethyl-6-t-butylphenol), 4,4′-thiobis(3-methyl-6-t-butylphenol), 4,4′-butylidenebis(3-methyl-6-t-butylphenol), and 3,9-bis[1,1-dimethyl-2-{β-(3-t-butyl-4-hydroxy-5-methylphenyl)propionyloxy}ethyl]2,4,8,10-tetraoxaspiro[5.5]undecane; and polymeric phenols such as 1,1,3-tris(2-methyl-4-hydroxy-5-t-butylphenyl)butane, 1,3,5-trimethyl-2,4,6-tris(3,5-di-t-butyl-4-hydroxybenzyl)benzene, tetrakis-[methylene-3-(3′,5′-di-t-butyl-4′-hydroxyphenyl)propionate]methane, bis[3,3′-bis(4′-hydroxy-3′-t-butylphenyl)butyric acid]glycol ester, 1,3,5-tris(3′,5′-di-t-butyl-4′-hydroxybenzyl)-s-triazine-2,4,6-(1H,3H,5H)trione, and tocophenol.

Examples of the hindered amine-based antioxidant include bis (1,2,2,6,6-pentamethyl-4-piperidyl)[[3,5-bis (1,1-dimethyl ethyl)-4-hydroxyphenyl]methyl]butyl malonate, bis(1,2,2,6,6-pentamethyl-4-piperidyl) sebacate, methyl-1,2,2,6,6-pentamethyl-4-piperidyl sebacate, and 4-benzoyloxy-2,2,6,6-tetramethylpiperidine.

Examples of the phosphorus-based antioxidant include phosphites such as triphenyl phosphite, diphenylisodecyl phosphite, phenyldiisodecyl phosphite, tris(nonylphenyl)phosphite, diisodecyl pentaerythritol phosphite, tris(2,4-di-t-butylphenyl) phosphite, cyclic neopentanetetraylbis(octadecyl)phosphite, cyclic neopentanetetraylbis(2,4-di-t-butylphenyl)phosphite, cyclic neopentanetetraylbis(2,4-di-t-butyl-4-methylphenyl)phosphite, and bis[2-t-butyl-6-methyl-4-{2-(octadecyloxycarbonyl)ethyl}phenyl]hydrogen phosphite; and oxaphosphaphenanthrene oxides such as 9,10-dihydro-9-oxa-10-phosphaphenanthrene-10-oxide, and 10-(3,5-di-t-butyl-4-hydroxybenzyl)-9,10-dihydro-9-oxa-10-phosphaphenanthrene-10-oxide.

Examples of the sulfur-based antioxidant include dodecanethiol, dilauryl-3,3′-thiodipropionate, dimyristyl-3,3′-thiodipropionate, and distearyl-3,3′-thiodipropionate.

In a case in which the curable composition contains an antioxidant, the content of the antioxidant is not particularly limited, but is preferably from 0.05 to 5 parts by mass and more preferably from 0.1 to 1 parts by mass per the total amount (100 parts by mass) of the curable compounds. When the content of the antioxidant is 0.05 parts by mass or greater, sufficient stability can be provided. In addition, when the content of the antioxidant is 5 parts by mass or less, coloration of the hard coat layer can be suppressed.

When the curable composition contains an antioxidant, the content thereof is not particularly limited, but is preferably from 0.05 to 5 parts by mass and more preferably from 0.1 to 3 parts by mass per 100 parts by mass of the polyorganosilsesquioxane. When the content of the antioxidant is 0.05 parts by mass or greater, sufficient stability can be provided. In addition, when the content of the antioxidant is 5 parts by mass or less, coloration of the hard coat layer can be suppressed.

The curable composition may further contain a solvent. The solvent is not particularly limited as long as the solvent is capable of dissolving the polyorganosilsesquioxane described above and any additives used as necessary, and does not inhibit polymerization. A single type of solvent may be used alone, or two or more types may be used in combination.

The solvent that is used is preferably one that can impart fluidity suitable for coating onto the hard coat layer and that can be easily removed by heating at a temperature at which the progression of polymerization can be suppressed, and preferably, a solvent having a boiling point (at 1 atm) of not higher than 170° C. is used (for example, an aromatic solvent such as toluene, xylene, and mesitylene; an ester such as butyl acetate; a ketone such as methyl isobutyl ketone and cyclohexanone; and an ether such as propylene glycol monomethyl ether and propylene glycol monomethyl ether acetate).

From the viewpoint of excelling in coatability, the solvent is preferably used in a range such that the concentration of nonvolatile content in the curable composition is, for example, preferably from 5 to 100 mass %, more preferably from 10 to 80 mass %, and particularly preferably from 20 to 70 mass %. However, the addition amount is not limited to the range described above, and an optimal addition amount should be selected to adjust to a viscosity at which an appropriate film thickness can be achieved. That is, when the usage amount of the solvent is in excess, the viscosity of the curable composition becomes low, and forming a coating film with an appropriate film thickness tends to be difficult. On the other hand, when the usage amount of the solvent is too low, the viscosity of the curable composition becomes too high, and it tends to be difficult to uniformly apply the curable composition onto the substrate.

The curable composition may further contain, as other components, commonly used additives, such as an inorganic filler, such as precipitated silica, wet silica, fumed silica, calcined silica, titanium oxide, alumina, glass, quartz, aluminosilicic acid, iron oxide, zinc oxide, calcium carbonate, carbon black, silicon carbide, silicon nitride, and boron nitride; an inorganic filler produced by treating the above filler with an organosilicon compound, such as an organohalosilane, organoalkoxysilane, and organosilazane; an organic resin fine powder, such as a silicone resin, an epoxy resin, and a fluororesin; a filler, such as a conductive metal powder of silver, copper, or the like, a curing auxiliary, a stabilizer (such as a light-resistant stabilizer, a heat stabilizer, and a heavy metal inactivator),an ultraviolet absorber (a triazine-based UV absorbers, a benzotriazole-based UV absorber, a benzophenone-based UV absorber, an oxybenzophenone-based UV absorber, a salicylate-based UV absorber, and a cyanoacrylate-based UV absorber), a flame retardant (such as a phosphorus-based flame retardant, a halogen-based flame retardant, and an inorganic flame retardant), a flame retardant auxiliary, a reinforcing material (such as an additional filler), a nucleating agent, a coupling agent (such as a silane coupling agent), a lubricant, a wax, a plasticizer, a releasing agent, an impact modifier, a hue modifier, a transparentizing agent, a rheology modifier (such as a fluidity modifier), a processability modifier, a colorant (such as a dye and a pigment), an antistatic agent, a dispersant, a surface modifier (such as a slipping agent), a matting agent, an antifoaming agent, a foam inhibitor, a deforming agent, an antibacterial agent, a preservative, a viscosity modifier, a thickening agent, a photosensitizer, and a foaming agent. A single type of the other components may be used alone, or two or more types may be used in combination. The content of the other components described above is not particularly limited, but is preferably from 100 parts by mass or less, more preferably from 30 parts by mass or less (for example, from 0.01 to 30 parts by mass), and still more preferably 10 parts by mass or less (for example, from 0.1 to 10 parts by mass), per 100 parts by mass of the total amount of the curable compounds.

Moreover, the curable composition does not contain a compound corresponding to a PFAS. Such configuration enables the curable composition not to use a PFAS, and the curable composition can comply with PFAS regulations.

The above-described curable composition can be prepared by agitating and mixing components described above at room temperature or under heating as necessary, but the preparation method is not limited thereto. Here, the curable composition can be used as a one-part composition that contains components mixed in advance and is used as is, or alternatively, the curable composition can be used as a multi-part (for example, two-part) composition two or more components of which are separately stored and then mixed at predetermined proportions before use.

The form of the curable composition is not particularly limited but is preferably a liquid at normal temperature (about 25° C.). More specifically, a liquid of the curable composition diluted with a solvent to 20% [in particular, a curable composition solution in which the proportion of methyl isobutyl ketone is 20 mass %] has a viscosity at 25° C. of preferably from 300 to 20000 mPa·s, more preferably from 500 to 10000 mPa·s, and even more preferably from 1000 to 8000 mPa·s. When the viscosity of the curable composition is 300 mPa·s or greater, the cured product (coating film) tends to further improve. On the other hand, when the viscosity thereof is 20000 mPa·s or less, the preparation and handling of the curable composition tend to be facilitated, and air bubbles tend to be less likely to remain in the cured product (coating film). Here, the viscosity of the curable composition is measured using a viscometer (trade name “MCR301”, available from Anton Paar GmbH) under conditions including a swing angle of 5%, a frequency of from 0.1 to 100 (1/s), and a temperature of 25° C.

The method for producing the hard coat layer is not particularly limited, and the hard coat layer can be produced in accordance with a known or commonly used method for producing a hard coat layer. For example, the hard coat layer can be produced by coating at least one surface of the substrate with the curable composition, and then if necessary, removing the solvent through drying, followed by curing the curable composition (curable composition layer). The curable composition application method and curing conditions are not particularly limited, and for example, can be appropriately selected from the below-described conditions.

As a method of applying and curing the hard coat layer, an ordinary coating method can be used. For example, a known method such as a dipping, roll coating, gravure coating, reverse coating, air knife coating, comma coating, die coating, screen printing, spray coating, gravure offset, and organic vapor deposition can be used. An example of the curing method is irradiation with light using, for example, a mercury lamp, a xenon lamp, a carbon arc lamp, a metal halide lamp, sunlight, an electron beam source, a laser light source, or an LED light source. Also note that when the hard coat layer is cured by irradiation with ultraviolet rays, for example, the cumulative irradiation amount is preferably from approximately 1 mJ/cm² to approximately 5000 mJ/cm².

The specific curing conditions are not particularly limited, but for example, the curable composition is first subjected to a heat treatment (pre-baking) at a temperature of preferably 60° C. or higher, more preferably 120° C. or higher, and even more preferably 150° C. or higher for preferably 10 seconds or longer, more preferably 30 seconds or longer, and even more preferably 60 seconds or longer, and is then irradiated with ultraviolet rays (radiation conditions (radiation dose): preferably 300 mJ/cm² or greater; radiation intensity: 100 mW/cm² or greater), and finally, is cured through heat treatment (aging) at a temperature of preferably 120° C. or higher for preferably 0.5 hours or longer. However, the curing conditions are not limited to this range, and the pre-baking temperature and time, and the aging temperature and time can be selected, as appropriate, according to the solvent that is used, and the ultraviolet radiation conditions can be selected, as appropriate, according to the curing agent that is used.

As described above, through application and curing, the curable composition can form a hard coat layer having a high surface hardness and toughness. The laminate including the hard coat layer produced as described above exhibits improved surface hardness of the hard coat layer while maintaining excellent bendability and bending durability.

In order to further improve the ability to re-coat the hard coat layer, the surface of the hard coat layer may be subjected to a surface treatment such as a corona discharge treatment for modifying the surface through irradiation with a corona discharge, a plasma discharge treatment, an ozone exposure treatment, or an excimer treatment. Among these treatments, the corona discharge treatment is more preferable from the viewpoint of being able to easily improve the ability to re-coat the hard coat layer.

The corona discharge treatment is a process in which the hard coat layer surface is treated by generating a non-uniform electric field around a pointed electrode (needle electrode) and generating a sustained discharge. The plasma discharge treatment is a process in which the hard coat layer surface is treated by generating positively and negatively charged particles activated through discharging in the atmosphere. The ozone exposure treatment is a process in which the hard coat layer surface is treated by generating ozone through ultraviolet irradiation using, for example, a low-pressure mercury lamp in the presence of oxygen. The excimer treatment is a process in which the hard coat layer surface is treated by ultraviolet irradiation or laser irradiation using an excimer lamp in a vacuum state.

The haze of the hard coat layer is preferably 1% or less, more preferably 0.7% or less, and even more preferably 0.5% or less. In addition, the lower limit of the haze is, for example, 0.1%. When the haze is 1% or less, the transparent laminate tends to be suitable for use in applications requiring a high transparency.

The thickness of the hard coat layer is preferably from 5 to 100 μm, and more preferably from 10 to 70 μm. Sufficient surface hardness can be exhibited by setting the thickness of the hard coat layer to 5 μm or greater. In addition, bendability is easily exhibited by setting the thickness thereof to 100 μm or less. When the hard coat layer is formed on both surfaces of the substrate, the thickness of at least one of the hard coat layers is preferably 5 μm or greater, and more preferably 10 μm or greater. Moreover, from the viewpoint of exhibiting bendability, the thickness of each of both hard coat layers is preferably 60 μm or less, and more preferably 50 μm or less.

### Image Display Device

One embodiment of the present disclosure is an image display device provided with the above-described laminate. In the image display device, the laminate is disposed, for example, with the hard coat layer configuring the surface of the viewing side. The image display device is not particularly limited, and examples thereof include display devices such as an organic electroluminescent display device, an inorganic electroluminescent display device, and a liquid crystal display device. In the display device, since the surface of the hard coat layer has sufficient surface hardness, scratches are less likely to occur on the surface, and the touch property is excellent. In addition, since the image display device has excellent bendability and bending durability, the image display device can also be used as a foldable display that can be rolled or the like. Furthermore, since sufficient surface hardness, bendability, and bending durability are exhibited, the image display device can be suitably used as a foldable device that includes the image display device.

Each aspect disclosed in the present specification can be combined with any other feature disclosed herein. Moreover, each of the configurations, combinations thereof, and the like in each of the embodiments are merely examples, and various additions, omissions, and other changes of the configurations may be made, as appropriate, without departing from the spirit of the present disclosure. The present disclosure is not limited by the embodiments and is limited only by the claims.

### EXAMPLES

An embodiment of the present disclosure will be described in detail below based on Examples.

### Production Example 1

### Polyorganosilsesquioxane Production

A 1000 mL flask (reaction vessel) equipped with a thermometer, a stirrer, a reflux condenser, and a nitrogen inlet tube was charged with 277.2 mmol (68.30 g) of 2-(3,4-epoxycyclohexyl)ethyltrimethoxysilane, 3.0 mmol (0.56 g) of phenyltrimethoxysilane, and 275.4 g of acetone under a nitrogen stream, and the temperature was raised to 50° C. To the mixture thus prepared, 7.74 g of a 5% potassium carbonate aqueous solution (2.8 mmol as potassium carbonate) was added over 5 minutes, after which 2800.0 mmol (50.40 g) of water was added over 20 minutes. Here, no significant temperature increase occurred during the additions. Subsequently, a polycondensation reaction was performed under a nitrogen stream for 5 hours while the temperature was maintained at 50° C.

Next, the reaction solution was cooled, and simultaneously, 137.70 g of methyl isobutyl ketone and 100.60 g of a 5% saline solution were added thereto. The solution was transferred to a 1 L separation funnel, and then 137.70 g of methyl isobutyl ketone was again added, and rinsing with water was performed. After the separation, the water layer was removed, and the lower layer liquid was rinsed with water until the lower layer liquid became neutral. The upper layer liquid was then fractioned, after which the solvent was distilled away from the upper layer liquid at 1 mmHg and 50° C., and 75.18 g of a colorless, transparent liquid product (an epoxy group-containing low-molecular weight polyorganosilsesquioxane: silsesquioxane of Production Example 1) containing 23 mass % of methyl isobutyl ketone was produced.

Note that when the product was analyzed, the number average molecular weight was found to be 2235, and the molecular weight dispersity was 1.54. A ratio [T3 form/T2 form] of T2 forms and T3 forms calculated from the ²⁹Si-NMR spectrum of the product was 11.9. The confirmation was performed through ¹H-NMR and ²⁹Si-NMR of the resulting epoxy group-containing low-molecular weight polyorganosilsesquioxane.

The molecular weight of the product was measured using the Shimadzu LC-20AD pump, the Shodex RI-504 detector, the Shodex GPC KF-602 and KF-603 columns, the Shodex GPC KF-G guard column, and THF as the solvent at a measurement temperature condition of 40° C. In addition, the ratio [T3 form/T2 form] of T2 forms and T3 forms in the product was measured through ²⁹Si-NMR spectrum measurements using the JEOL ECA500 (500 MHz).

### Preparation of Hard Coat Agent

The materials described in Table 1 were mixed with the above silsesquioxane at the constituent proportions shown in Table 1, and hard coat agents of the Example and Comparative Example were thereby produced. The content proportions shown in the table are the blending proportions of the respective components. For the silsesquioxane of Production Example 1 (active component: 77 mass %) and RS-57 (active component: 20 mass %), the content proportions are the solution values, and for the other components, the content proportions are the values of the active component.

TABLE 1

| | | | Comparative |
|---|---|---|---|
| | | Examples | Example |
| | | Constituent | Constituent |
| | | Proportion | Proportion |
| | | (parts by | (parts by |
| | Material Name | mass) | mass) |
| Curable | Silsesquioxane of | 66.8 | 66.8 |
| compound | Production Example 1 | | |
| | 200PA-E5 | 1.5 | 1.5 |
| | Epolight 1600N | 6.2 | 6.2 |
| Radical | Omnirad 127 | 0.2 | 0.2 |
| polymerization | | | |
| initiator | | | |
| Cationic | Salt of triarylsulfonium | 0.5 | 0.5 |
| polymerization | and tetrapentafluoro- | | |
| initiator | phenylgallium | | |
| Antioxidant | ADK STAB AO-20 | 0.12 | 0.12 |
| Leveling agent | KY1203 | — | 0.4 |
| | RS-57 | 0.4 | — |
| Solvent | MIBK | 8.4 | 8.4 |
| | MEK | 15.8 | 15.8 |

Components listed in Table 1 are described in detail below.

200PA-E5: a product of the trade name “Epoxy Ester 200PA-E5”, available from Kyoeisha Chemical Co., Ltd. (a compound having one or more cationically polymerizable groups and one or more radically polymerizable groups per molecule)

Epolight 1600N: a product of the trade name “Epolight 1600N”, available from Kyoeisha Chemical Co., Ltd. (an aliphatic compound having two or more cationically polymerizable groups per molecule)

Omnirad 127: a product of the trade name “Omnirad 127”, available from IGM Resins B. V. (a radical polymerization initiator)

Salt of triarylsulfonium and tetrapentafluorophenylgallium: photocationic polymerization initiator

ADK STAB AO-02: a product of the trade name “ADK STAB AO-02”, available from Adeka Corporation (antioxidant)

KY1203: a product of the trade name “KY1203”, containing a compound corresponding to a PFAS, available from Shin-Etsu Chemical Co., Ltd. (leveling agent)

RS-57: a product of the trade name “RS-57”, silicone resin containing no compound corresponding to a PFAS, available from DIC Corporation (leveling agent)

MIBK: Methyl isobutyl ketone (a solvent)

MEK: Methyl ethyl ketone (a solvent)

### Examples 1 and 2

Wire bars #12 and #22 were respectively used to apply the hard coat agent of the above Example onto PET substrates (trade name “TA069”, available from Toyobo Co., Ltd.) at respective amounts resulting in thicknesses of 10 μm and 20 μm after curing of the hard coat agent, after which the coated PET substrates were placed in an oven at 80° C. for 1 minute and then in an oven at 120° C. for 2 minutes. Next, ultraviolet rays were irradiated thereon at an illuminance of 300 mJ/cm² using a high-pressure mercury lamp, and a hard coat layer was thereby formed. Subsequently, the resulting products were left in an oven at 120° C. for 60 minutes, and laminates of Examples 1 and 2 were produced.

### Comparative Examples 1 and 2

Laminates of Comparative Examples 1 and 2 were produced in the same manner as the laminates of Examples 1 and 2, with the exception that wire bars #12 and #22 were used to apply the hard coat agent of the Comparative Example onto respective PET substrates (trade name “TA069”, available from Toyobo Co., Ltd.) at respective amounts resulting in cured thicknesses of 10 μm and 20 μm.

### Evaluation

The laminates produced in the Examples and Comparative Examples were subjected to the following evaluations, and the results are presented in Table 2.
(1) Haze

The haze values (%) of the laminates of Examples 1 and 2 and Comparative Examples 1 and 2 were measured using a haze measuring device (trade name “NDH-5000W”, available from Nippon Denshoku Industries Co., Ltd.). The haze values were measured in accordance with JIS K7136.
(2) Total Light Transmittance

The total light transmittance (%) of the laminates of Examples 1 and 2 and Comparative Examples 1 and 2 was measured using a total light transmittance measuring device (trade name “NDH-5000W”, available from Nippon Denshoku Industries Co., Ltd.). This measurement was implemented in accordance with JIS K7105.
(3) Pencil Hardness

The pencil hardness of the hard coat layer surface of each of the laminates of Examples 1 and 2 and Comparative Examples 1 and 2 was evaluated in accordance with JIS K5600-5-4 (750 g load).
(4) Wear resistance

#0000 steel wool was rubbed back and forth 1000 times at a load of 750 g/cm² on the surface of the hard coat layer of each of the laminates of Examples 1 and 2 and Comparative Examples 1 and 2, and the presence or absence of scratches on the surfaces of the hard coat layers was assessed.
(5) Bendability

For each of the laminates of Examples 1 and 2 and Comparative Examples 1 and 2, a cylindrical mandrel bending tester (trade name “Bending Tester (cylindrical mandrel method)”, available from TP Giken K.K.) was used to measure, through the cylindrical mandrel method in accordance with JIS K5600-5-1 (1999), the bendability both in a case in which the hard coat layer was oriented inward and in a case in which the hard coat layer was oriented outward.
(6) Continuous Bending Durability

The continuous bending durability of the laminates of Examples 1 and 2 and Comparative Examples 1 and 2 was measured using a planar body no-load U-shaped expansion/contraction tester (trade name “Z-044”, available from Yuasa System Co., Ltd.). Operations were carried out 10000 times at a rate of 30 to 60 operations/minute, where in a single operation, the laminate is subjected to 180° bend from a unbended conformation to have a bending radius of 4.0 mm in a direction to make the surface of the hard coat layer convex, and then once again is brought back to the unbended conformation. After these operations, the presence or absence of cracks in the hard coat layer and in the PET substrate was assessed.

TABLE 2

| | | Comparative | Comparative | | |
|---|---|---|---|---|---|
| | | Example 1 | Example 2 | Example 1 | Example 2 |
| Optical | Film thickness (μm) | 10 | 20 | 10 | 20 |
| properties | Haze (%) | 0.4 | 0.5 | 0.4 | 0.5 |
| | Total light transmittance | 91.4 | 91.3 | 91.6 | 91.4 |
| | (%) | | | | |
| Pencil | 750 g load | H | 3H | H | 3H |
| Hardness | | | | | |
| Wear | After 1000 reciprocations | No scratches | No scratches | No scratches | No scratches |
| resistance | with 750 g load | | | | |
| Bendability | Hard coat layer inward | 2 mm φ | 2 mm φ | 2 mm φ | 2 mm φ |
| | Hard coat layer outward | 3 mm φ | 4 mm φ | 4 mm φ | 4 mm φ |
| Bending | Hard coat layer outward | No cracking | No cracking | No cracking | No cracking |
| durability | | | | | |

It was confirmed that the laminates of the Examples exhibited sufficient wear resistance and bendability without using a fluorine compound and exhibited the same hardness and bendability as the laminates of the Comparative Examples, which used a compound corresponding to a PFAS.

Hereinafter, variations of the invention according to the present disclosure will be described.

### Addendum 1

A laminate including:
a substrate; and
a hard coat layer laminated on at least one surface of the substrate, the hard coat layer containing no compound corresponding to a PFAS,
wherein
the laminate has a minimum bendable radius of 5 mm or less in a cylindrical mandrel test in which the laminate is bent with a surface of the hard coat layer of the laminate being convex.

### Addendum 2

The laminate according to addendum 1, wherein the number of operations until a crack occurs in the hard coat layer is 10000 or more in a bending durability test of the hard coat layer as follows:

Bending Durability Test:

The operations are carried out at a rate of 30 to 60 operations/minute, where in a single operation, the laminate is subjected to 180° bend from a unbended conformation to have a bending radius of 4.0 mm in a direction to make the surface of the hard coat layer convex, and then once again is brought back to the unbended conformation.

### Addendum 3

The laminate according to addendum 1 or 2, wherein no visible scratches are generated on the hard coat layer when the hard coat layer is subjected to a steel wool abrasion test in which #0000 steel wool is rubbed back and forth 1000 times on the surface of the hard coat layer while a load of 750 g/cm² is applied.

### Addendum 4

The laminate according to any one or addenda 1 to 3, wherein the hard coat layer has a haze of 1.0% or less.

### Addendum 5

The laminate according to any one of addenda 1 to 4, wherein the laminate has a haze of 7% or less.

### Addendum 6

The laminate according to any one of addenda 1 to 5, wherein the hard coat layer is a cured product of a curable composition containing one or more curable compounds, and
the curable composition contains a polyorganosilsesquioxane as the one or more curable compounds.

### Addendum 7

The laminate according to addendum 6, wherein the curable composition contains a compound having one or more cationically polymerizable groups and one or more radically polymerizable groups per molecule.

### Addendum 8

The laminate according to addendum 6 or 7, wherein the curable composition further contains a curing catalyst.

### Addendum 9

The laminate according to addendum 8, wherein the curing catalyst includes a cationic polymerization initiator.

### Addendum 10

The laminate according to addendum 8 or 9, wherein the curing catalyst includes a radical polymerization initiator.

### Addendum 11

The laminate according to any one of addenda 6 to 10, wherein the curable composition further contains a radically curable polyorganosiloxane.

### Addendum 12

The laminate according to any one of addenda 6 to 11, wherein the curable composition further contains an aliphatic compound having two or more cationically polymerizable groups per molecule.

### Addendum 13

The laminate according to any one of addenda 1 to 12, wherein the substrate is a transparent substrate.

### Addendum 14

The laminate according to any one of addenda 1 to 13, further including a surface protection film on at least one surface thereof.

### Addendum 15

The laminate according to any one of addenda 1 to 14, wherein the hard coat layer is provided on one surface of the substrate, and a tacky adhesive layer is provided on the other surface of the substrate.

### Addendum 16

An image display device including the laminate described in any one of addenda 1 to 15.

### Addendum 17

The image display device according to addendum 16, wherein the image display device is a foldable display.

### Addendum 18

The image display device according to addendum 16 or 17, wherein the image display device is an organic electroluminescent display device.

### Addendum 19

A foldable device including the image display device described in any one of addenda 16 to 18.

1. A laminate comprising:
a substrate; and
a hard coat layer laminated on at least one surface of the substrate, the hard coat layer comprising no compound corresponding to a PFAS,
wherein
the laminate has a minimum bendable radius of 5 mm or less in a cylindrical mandrel test in which the laminate is bent with a surface of the hard coat layer of the laminate being convex.

2. The laminate according to claim 1, wherein the number of operations until a crack occurs in the hard coat layer is 10000 or more in a bending durability test of the hard coat layer as follows:
Bending Durability Test:
The operations are carried out at a rate of 30 to 60 operations/minute, where in a single operation, the laminate is subjected to 180° bend from a unbended conformation to have a bending radius of 4.0 mm in a direction to make the surface of the hard coat layer convex, and then once again is brought back to the unbended conformation.

3. The laminate according to claim 1, wherein no visible scratches are generated on the hard coat layer when the hard coat layer is subjected to a steel wool abrasion test in which #0000 steel wool is rubbed back and forth 1000 times on the surface of the hard coat layer while a load of 750 g/cm² is applied.

4. The laminate according to claim 1, wherein the hard coat layer has a haze of 1.0% or less.

5. The laminate according to claim 1, wherein the laminate has a haze of 7% or less.

6. The laminate according to claim 1, wherein the hard coat layer is a cured product of a curable composition comprising one or more curable compounds, and
the curable composition comprises a polyorganosilsesquioxane as the one or more curable compounds.

7. The laminate according to claim 6, wherein the curable composition comprises a compound having one or more cationically polymerizable groups and one or more radically polymerizable groups per molecule.

8. The laminate according to claim 6, wherein the curable composition further comprises a curing catalyst.

9. The laminate according to claim 8, wherein the curing catalyst comprises a cationic polymerization initiator.

10. The laminate according to claim 8, wherein the curing catalyst comprises a radical polymerization initiator.

11. The laminate according to claim 6, wherein the curable composition further comprises a radically curable polyorganosiloxane.

12. The laminate according to claim 6, wherein the curable composition further comprises an aliphatic compound having two or more cationically polymerizable groups per molecule.

13. The laminate according to claim 1, wherein the substrate is a transparent substrate.

14. The laminate according to claim 1, further comprising a surface protection film on at least one surface thereof.

15. The laminate according to claim 1, wherein the hard coat layer is provided on one surface of the substrate, and a tacky adhesive layer is provided on the other surface thereof.

16. An image display device comprising the laminate described in claim 1.

17. The image display device according to claim 16, wherein the image display device is a foldable display.

18. The image display device according to claim 16, wherein the image display device is an organic electroluminescent display device.

19. A foldable device comprising the image display device described in claim 16.
